(19) United States
(12) Patent Application Publication
(10) Pub. No.: US 2024/0203682 A1
(43) Pub. Date: Jun. 20, 2024

(54) ION BEAM DEVICE AND EMITTER TIP MILLING METHOD

(71) Applicant: HITACHI HIGH-TECH CORPORATION, Tokyo (JP)

(72) Inventors: Shinichi MATSUBARA, Tokyo (JP); Noriaki ARAI, Tokyo (JP)

(21) Appl. No.: 18/287,316

(22) PCT Filed: Sep. 13, 2021
(86) PCT No.: PCT/JP2021/033543

§ 371 Date: Oct. 18, 2023

(51) Int. Cl. H01J 37/08; H01J 37/12; H01J 37/32

(52) U.S. Cl. CPC H01J 37/08; H01J 37/12; H01J 37/32449; H01J 2237/0807

(57) ABSTRACT

An object of the invention is to provide an ion beam device capable of sharpening an emitter tip end to an atomic level with high reproducibility while reducing a device downtime. The ion beam device according to the invention measures a current of a helium ion beam, and switches, according to a measurement result, between a first operation of adjusting a flow rate of a nitrogen gas or an oxygen gas and a second operation of adjusting an extraction voltage.

### TECHNICAL FIELD

The present invention relates to an ion beam device.

### BACKGROUND ART

An electron beam is focused after passing through an electromagnetic field lens, a sample is irradiated with the focused electron beam while being scanned with the focused electron beam, and charged particles (secondary electrons) emitted from the sample are detected, so that a surface structure of the sample can be observed. Such a microscope is referred to as a scanning electron microscope (SEM).

### Description of a Focused Ion Beam (FIB) Device

A three-dimensional structure of a sample can be evaluated with high resolution in a short time by using a gas field ionization source (GFIS) together with an FIB optical system as an ion source. In the GFIS, preferably, a high voltage is applied to an emitter tip made of a metal and having a radius of curvature of about 100 nm or less at a tip end, an electric field is concentrated at the tip end, a gas (an ionized gas) is introduced into the vicinity of the tip end, and gas molecules are field ionized and extracted as an ion beam.

In a scanning ion microscope using a GFIS (GFIS-SIM), since an ion beam emitted from the GFIS has a smaller energy width and a smaller light source size than an ion beam emitted from an ion source made of a liquid metal or an ion source using a plasma phenomenon, the ion beam emitted from the GFIS can be finely focused. In order to make the GFIS have brightness sufficient for practical use, a tip end of an emitter needs to be sharpened at an atomic level.

The GFIS is characterized in that ion species to be extracted can be changed by changing gas molecules. When a sample surface is to be observed, hydrogen or helium having a small mass is extracted, and when the sample surface is to be processed, ions having a relatively large mass, such as neon or argon, are extracted, so that damage to the sample during observation can be reduced, and conversely, a processing speed during sample processing can be increased.

An ion beam emitted from the GFIS is characterized in that a wavelength is short when an acceleration voltage is the same as that of an electron beam. Accordingly, an aberration due to an influence of diffraction is reduced, and therefore, an aperture angle of the ion beam can be reduced. This means that a focus depth of an observation image (an SIM image) becomes deep. This is a property that works advantageously when objects at different positions in a depth direction are observed at the same time. Since a scattering region in a sample is narrow even when the sample is irradiated at high acceleration and a secondary electron detection signal is obtained only from an extreme surface, it is possible to perform observation in which both sample surface sensitivity and high resolution are achieved. On the other hand, in an SEM, it is required to reduce an acceleration voltage of an electron beam in order to obtain an image sensitive to a sample surface, and in general, there is a disadvantage in that acceleration is reduced and resolution is lowered.

When observation and a processing function in a GFIS-SIM are switched, different beams are emitted from a single beam column, which is different from a focused ion beam SEM (FIB-SEM) in which both an FIB and an SEM are provided. Therefore, a sample can be irradiated with different ion beams from the same direction, and switching can be performed while optimally maintaining a distance (a working distance) between a lens and the sample which is a necessary condition that affects resolution. Brightness and energy dispersion of an ion beam are equivalent to those of an electron beam extracted from a field emission electron gun. Therefore, a GFIS can theoretically acquire a three-dimensional structure of a sample with higher resolution than an FIB-SEM.

PTL 1 discloses (see abstract) a technique of “a method for preparing a sharpened needle-shaped emitter including: an electropolishing step of electrolytically polishing a tip end portion of a conductive emitter material to taper towards a tip end; and an etching step of further sharpening the tip end by electric field-induced gas etching processing in a state in which an applied voltage is maintained constant while observing, using a field ion microscope, a crystal structure of the tip end at a sharp portion with the tip end as an apex to make the number of atoms constituting a tip of the tip end equal to or less than a predetermined number” with “to obtain an emitter in which a crystal structure of an emitter tip end can be returned to an original state with high reproducibility by rearranging atoms through a treatment, an increase in an extraction voltage after the treatment can be prevented, and the emitter can be continuously used for a long time” as a subject.

PTL 2 discloses (see abstract) a technique of “a focused ion beam device 1 according to the invention including an emitter 10 having a sharpened tip end, an ion source chamber 20 accommodating the emitter, a gas supply unit 11 configured to supply a gas having ionization energy lower than that of helium to the ion source chamber 20, and an extraction power supply unit 15 configured to apply an extraction voltage to between the emitter 10 and an extraction electrode 14 to ionize a gas at the tip end of the emitter 10 into gas ions and then extract the gas ions to the extraction electrode 14, in which the extraction power supply unit 15 applies the extraction voltage such that the number of bright spots of a field ion image in an ion beam emitted from the emitter 10 is one” with “providing a focused ion beam device capable of stably obtaining an ion current regardless of a terminal end structure of an emitter tip end, and a focused ion beam irradiation method” as a subject.

### CITATION LIST

### Patent Literature

PTL 1: JP2020-161262A
PTL 2: JP2014-191864A

### SUMMARY OF INVENTION

### Technical Problem

As described above, in order to obtain an ion beam having brightness at a practical level in a GFIS, it is required to obtain enough sharpness to terminate a tip end of an emitter by the number of atoms. An atomic sharpness structure may be suddenly damaged by, for example, adsorption of a chemically active gas, and it is required to reproduce sharpness with high reproducibility each time. It is basically impossible to observe a sample using a device during formation processing or reproducing processing for obtaining atomic sharpness, and processing times for these pieces of processing are basically fairly short in order to increase an operation rate of the device.

There are various methods for atomic sharpness processing. For example, there is (a) a method in which platinum, iridium, or the like, which is a precious metal, is deposited on a single crystal of tungsten that is previously sharpened to a certain extent by electrolytic etching processing on an emitter to form a film, and then the film is heated in vacuum to form a pyramidal atomic arrangement at an emitter tip end, and (b) a method in which a single crystal of tungsten is heated in an electric field to form an atomic arrangement in a similar manner. These methods use a phenomenon in which a single crystal of tungsten is self-formed into a more thermodynamically stable shape by heating. On the other hand, there is a method (field chemical assist etching (FCE)) in which a needle-shaped metal single crystal is removed to shave a side portion of an emitter using a chemical action of a reaction gas such as a nitrogen gas or an oxygen gas in an electric field, so that a structure of several atoms is left at a tip end. Different from the self-forming methods, this method requires adjustment of an intensity of the electric field, gas pressure, and the like each time to obtain atomic sharpness of the emitter, and since a beam can be emitted during processing, a shape of the tip end can be monitored each time using the latter method. Therefore, it is considered that this method has more advantages in terms of certainty of processing than the self-forming method.

As a method of monitoring a shape of an emitter, it is optimum to use a field ion microscope (FIM) capable of observing a tip end of a metal needle with atomic level resolution. In this method, a position-sensitive ion particle detector represented by a micro channel plate (MCP) or the like faces the metal needle such as a single crystal of tungsten used for the emitter. Further, a structure of the tip end of the metal needle can be monitored by introducing an image gas such as a helium gas to a periphery of the metal needle after applying a high voltage to the metal needle and detecting emitted image gas ions by the MCP. FCE processing can be repeatedly and easily executed with high reproducibility using monitoring performed by the FIM.

The monitoring performed by FIM requires the position-sensitive detector as described above. In order to monitor a phenomenon such as occurrence of FCE processing outside an emitter tip end, it is required to detect image gas ions emitted from an emitter at a wide angle. These requirements are basically difficult to be compatible with a GFIS-SIM.

Since an MCP used as a position-sensitive detector has a porous structure, when the MCP is introduced into a vacuum device, there is a possibility that an impurity gas is emitted into the vacuum device due to a degassing phenomenon. In a GFIS, the presence of the impurity gas causes an ion beam to be unstable. Since the MCP is a fairly expensive element and is a product having limited life, periodic replacement is required. Further, a high-voltage insulating structure and a plurality of power supplies are required. These are factors that greatly increase manufacturing costs of a GFIS-SIM.

In relation to an ion beam introduction angle, when the ion beam introduction angle is wide, GFIS-SIM resolution is adversely affected. When a position directly below an emitter tip and an extraction electrode is selected as a position of an MCP, an ion beam introduction angle can be widened, but a distance between the extraction electrode and a subsequent electrostatic lens element is inevitably increased by a thickness of the MCP, and thus an influence of a lens aberration is increased and resolution is lowered. In the case of arranging the MCP under a structure of the emitter tip, the extraction electrode, and the electrostatic lens, the introduction angle is limited by an opening diameter of the electrostatic lens. When the opening diameter is increased, the introduction angle naturally increases, but a lens aberration and resolution is lowered. It is also conceivable to adjust the position of the MCP by providing a mechanism for inserting and removing the MCP, but insertion and removing processing becomes a device downtime, which leads to a decrease in efficiency of the device.

A nitrogen gas or an oxygen gas used in FCE has a large chemical action on a metal such as tungsten and iridium and is excellent in processing speed, but has a disadvantage in that an aggregation temperature is considerably higher than that of a helium gas or a hydrogen gas used in a GFIS-SIM. Although brightness of an ion beam emitted from a GFIS depends on a cooling temperature of an emitter, a vicinity of an aggregation temperature of a used gas is often optimum for increasing the brightness of the ion beam. That is, it means that an optimum operation temperature of the GFIS that emits helium or hydrogen is lower than an aggregation temperature of a nitrogen gas or an oxygen gas. Specifically, a temperature difference is about 50 K. For example, a failure occurs in an atomic structure of an emitter tip end in a GFIS that operates at an optimum temperature for a hydrogen ion beam. In order to use a nitrogen gas to readjust the atomic structure in FCE, an operation temperature has to be increased once above an aggregation temperature of the nitrogen gas. Processing of increasing the temperature of the GFIS and processing of lowering the temperature after FCE require approximately half a day at most. This causes a problem that a device downtime increases. In addition, when a nitrogen gas is introduced at an optimal brightness temperature, the nitrogen gas is aggregated, and there is a problem that a precise adjustment of gas pressure required for FCE becomes fairly difficult.

The invention has been made in view of the above problems, and an object of the invention is to provide an ion beam device capable of sharpening an emitter tip end to an atomic level with high reproducibility while reducing a downtime of the device.

### Solution to Problem

An ion beam device according to the invention measures a current of a helium ion beam, and switches, according to a measurement result, between a first operation of adjusting a flow rate of a nitrogen gas or an oxygen gas and a second operation of adjusting an extraction voltage. An emitter processing method according to the invention can switch between a first processing mode for sharpening an emitter tip using a nitrogen gas or an oxygen gas and a second mode for sharpening the emitter tip using a hydrogen gas.

### Advantageous Effects of Invention

According to the ion beam device of the invention, FCE processing using nitrogen can be performed regardless of position-sensitive detection of an MCP or the like. Accordingly, the emitter can have atomic sharpness with high reproducibility. Further, sharpness of an emitter tip end can be determined according to a measurement result of the current of the helium ion beam measured by a current detector using a Faraday cup or the like on a sample or in an optical column, and thus a device downtime can be reduced. According to the emitter processing method of the invention, the hydrogen ion beam can be used for both sharpening and monitoring of the emitter by using the hydrogen ion beam in combination. Accordingly, monitoring can be performed without using a detector such as an MCP, and a downtime due to a temperature adjustment of the device can be reduced.

### BRIEF DESCRIPTION OF DRAWINGS

FIG. 1 is a configuration diagram showing an ion beam device 1000 according to Embodiment 1.

FIG. 2 is an enlarged diagram showing a member arrangement around an emitter electrode 11.

FIG. 3 is an enlarged diagram showing another example of a member arrangement around the emitter electrode 11.

FIG. 4 is a schematic diagram showing a state in which a tip end of the emitter electrode 11 is sharpened by FCE processing.

FIG. 5 shows data indicating transition of a current amount of a helium ion beam whose detection angle is appropriately limited, which is actually detected during the FCE processing.

FIG. 6 is an enlarged view showing a periphery of the emitter electrode 11 and showing a state in which an introduction angle of a helium ion beam is limited.

FIG. 7 is a flowchart showing a procedure for performing the FCE processing using a hydrogen gas.

### DESCRIPTION OF EMBODIMENTS

### Embodiment 1: Device Configuration

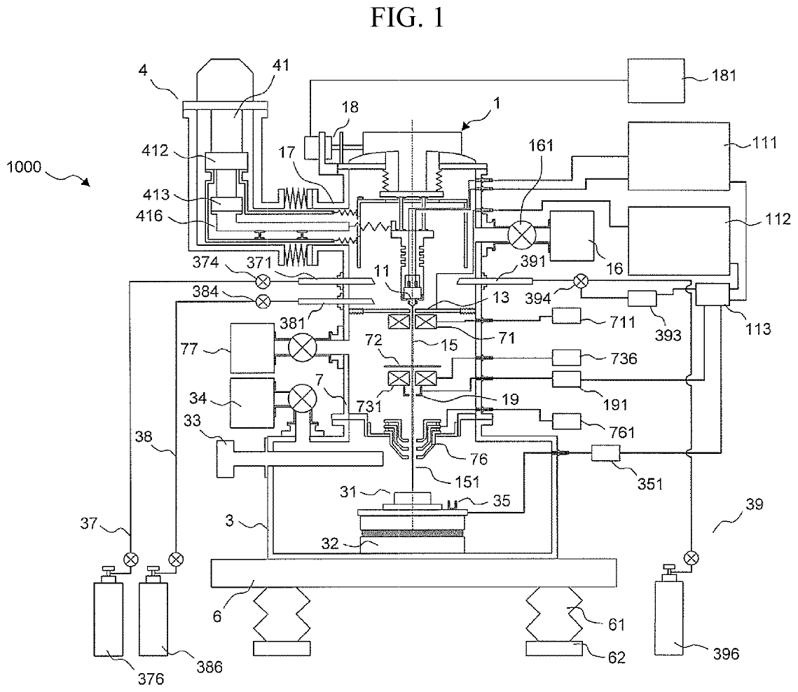

FIG. 1 is a configuration diagram showing an ion beam device 1000 according to Embodiment 1 of the invention. A gas field ionization source 1 includes an emitter electrode (an emitter tip) 11 having a needle-shaped tip end, an extraction electrode 13, a refrigerator 4, a vacuum chamber 17, a vacuum evacuation device 16, gas introduction mechanisms 37 and 38, and high-voltage power supplies 111 and 112.

The extraction electrode 13 has an opening at a position facing the emitter electrode 11. The refrigerator 4 cools the emitter electrode 11. The refrigerator 4 includes a refrigerator body 41, and the refrigerator body 41 includes a first stage 412 and a second stage 413. The vacuum chamber 17 accommodates the emitter electrode 11, the first stage 412, and the second stage 413. The vacuum evacuation device 16 evacuates the vacuum chamber 17. The gas introduction mechanism 37 supplies a hydrogen gas into the vacuum chamber 17. The high-voltage power supply 111 applies a voltage to the emitter electrode 11, and the high-voltage power supply 112 applies a voltage to the extraction electrode 13. A gas in the vicinity of the tip end of the extraction electrode 11 is positively ionized by a potential difference between the emitter electrode 11 and the extraction electrode 13 to form a strong electric field.

The high-voltage power supplies 111 and 112 can be controlled independently of each other, and an acceleration voltage of an ion beam and an extraction voltage for forming an ionization electric field can be controlled independently of each other by independently controlling the high-voltage power supplies 111 and 112. In order to freely change an acceleration voltage of an ion beam regardless of a magnitude of ionization energy, it is desirable that the high-voltage power supply 112 connected to the extraction electrode 13 be a power supply capable of outputting both positive and negative outputs or a power supply having a negative polarity based on a potential supplied by the high-voltage power supply 111. Accordingly, the acceleration voltage of the ion beam can be set to be lower than an extraction voltage required for extracting hydrogen ions.

The gas introduction mechanism 37 includes a gas nozzle 371, a gas flow rate adjusting valve 374, and a gas cylinder 376. The gas nozzle 371 introduces a gas into the vacuum chamber 17. The gas flow rate adjusting valve 374 adjusts a flow rate of the gas. The gas cylinder 376 stores a hydrogen gas.

The gas introduction mechanism 38 includes a gas nozzle 381, a gas flow rate adjusting valve 384, and a gas cylinder 386. The gas nozzle 381 introduces a gas into the vacuum chamber 17. The gas flow rate adjusting valve 384 adjusts a flow rate of the gas. The gas cylinder 386 stores a helium gas.

A gas introduction mechanism 39 includes a gas nozzle 391, a gas flow rate adjusting valve 394, and a gas cylinder 396. The gas nozzle 391 introduces a gas into the vacuum chamber 17. The gas flow rate adjusting valve 394 adjusts a flow rate of the gas. The gas cylinder 396 stores a nitrogen gas.

First, a high voltage is applied between the emitter electrode 11 and the extraction electrode 13 in order to emit an ion beam 15 from the emitter electrode 11 of the gas field ionization source 1. The application of the high voltage causes an electric field to concentrate on a tip end of the emitter electrode 11. When an intensity of the electric field formed at the tip end becomes high enough for positively ionizing hydrogen and the gas introduction mechanism 37 introduces a gas containing a hydrogen gas into the vacuum chamber 17 in this state, a hydrogen ion beam is emitted from the tip end of the emitter electrode 11. When the intensity of the electric field formed at the tip end becomes high enough for positively ionizing helium and the gas introduction mechanism 38 introduces a gas containing a helium gas into the vacuum chamber 17 in this state, a helium ion beam is emitted from the tip end of the emitter electrode 11. As for gases such as neon, argon, krypton, nitrogen, and oxygen, an ion beam can be extracted by suitably adjusting a voltage and introducing a gas in a similar manner.

When no gas is introduced by the gas introduction mechanisms 37, 38, 39, the inside of the vacuum chamber 17 is maintained at an ultra-high vacuum of 10⁻⁷ Pa or less. In order to reach an ultra-high vacuum in the vacuum chamber 17, so-called baking for heating the entire vacuum chamber 17 to a high temperature may be included in a start-up operation of the gas field ionization source 1.

In order to increase brightness of an ion beam, it is preferable to adjust a cooling temperature of the emitter electrode 11 by the refrigerator 4. The refrigerator 4 cools the inside of the gas field ionization source 1, the emitter electrode 11, the extraction electrode 13, and the like. The refrigerator 4 may be, for example, a mechanical refrigerator such as a Gifford McMahon type (GM type) refrigerator or a pulse tube type refrigerator, or a refrigerant such as liquid helium, liquid nitrogen, or solid nitrogen. FIG. 1 shows a configuration in which a mechanical refrigerator is used. The mechanical refrigerator includes the first stage 412 and the second stage 413 of the refrigerator body 41. Heat from the second stage 413 is transferred to the emitter electrode 11, the extraction electrode 13, and the like by a heat transfer unit 416, and the emitter electrode 11 and the extraction electrode 13 are cooled.

A cooling temperature of the first stage 412 is lower than that of the second stage. The first stage 412 may cool a heat radiation shield. The heat radiation shield covers the second stage of the refrigerator, and more preferably covers the emitter electrode 11 and the extraction electrode 13. The heat radiation shield can reduce an influence of thermal radiation from the vacuum chamber 17, and accordingly, the second stage 413, the emitter electrode 11, the extraction electrode 13, and the like can be efficiently cooled.

The heat transfer unit 416 may be made of a metal having high thermal conductivity, such as copper, silver, or gold. In order to reduce an influence of thermal radiation, a surface may be subject to surface processing such as gold plating so that the surface has metallic luster. When a vibration generated by the refrigerator 4 is transmitted to the emitter electrode 11, there is an influence such as deterioration of resolution of a sample observation image using an ion beam. Therefore, a part of the heat transfer unit 416 may be implemented by a flexible component such as a metal wire in which the vibration is less likely to be transmitted. For the same reason, the heat transfer unit 416 may transfer heat to the emitter electrode 11 and the extraction electrode 13 by circulating a gas or liquid cooled using the refrigerator 4. When such a configuration is used, the refrigerator 4 can be provided at a position separated from a main body of the ion beam device 1000.

A temperature adjusting unit may be provided in the first stage 412, the second stage 413, and the heat transfer unit 416. The temperature adjusting unit adjusts a temperature of the emitter electrode 11 to increase brightness of each ion beam, thereby improving a signal-to-noise ratio during sample observation and a throughput during sample processing.

In order to increase the brightness of the ion beam, pressure of a gas introduced into the vacuum chamber 17 may be optimized. A total current amount of ions emitted from the emitter electrode 11 can be adjusted by a gas pressure value. A hydrogen gas is introduced from the gas cylinder 376 by adjusting a flow rate of the hydrogen gas through the gas flow rate adjusting valve 374. Pressure in the vacuum chamber 17 is determined by balance between a gas exhaust amount of the vacuum evacuation device 16 and the flow rate of the introduced hydrogen gas. The gas exhaust amount may be adjusted by providing a flow rate adjusting valve 161 between the vacuum evacuation device 16 and the vacuum chamber 17.

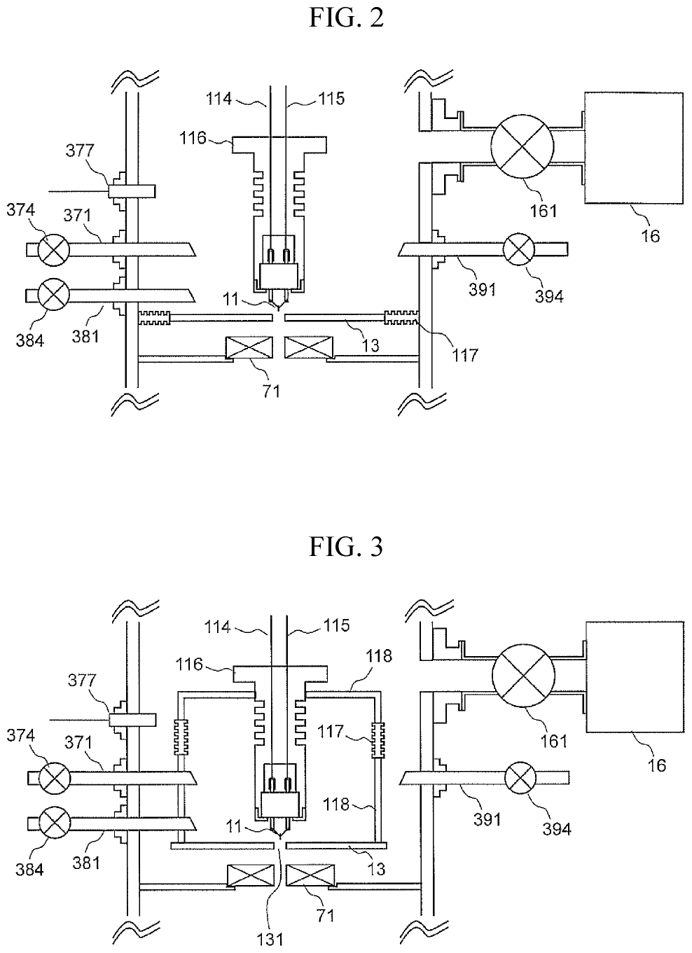

FIG. 2 is an enlarged diagram showing a member arrangement around the emitter electrode 11. When a gas is introduced from the gas introduction mechanism 37 to the entire inside of the vacuum chamber 17 at a high gas pressure, heat exchange occurs via the gas introduced to between the emitter electrode 11 and the vacuum chamber 17, so that the emitter electrode 11 is not sufficiently cooled and a failure such as condensation in the vacuum chamber 17 occurs. In addition, when a hydrogen gas pressure is high over the entire optical path of the ion beam 15 emitted from the emitter electrode 11, a part of the ion beam 15 is scattered, and a defect such as poor convergence of the beam occurs. Therefore, pressure of a gas introduced into the vacuum chamber 17 is preferably about 0.1 Pa or less.

FIG. 3 is an enlarged diagram showing another example of a member arrangement around the emitter electrode 11. When it is required to further increase introduction pressure to be higher than preferable gas pressure, a vacuum partition wall 118 may be provided as an inner wall surrounding the emitter electrode 11 inside the vacuum chamber 17. When the vacuum partition wall 118 is provided in a manner of surrounding the extraction electrode 13, a part of the extraction electrode 13 other than a hole for allowing the ion beam 15 to pass therethrough is maintained airtight, and a gas is introduced from the gas nozzle 371 into the inside of the inner wall, gas pressure can be increased only around the emitter electrode 11. With such a configuration, the gas pressure around the emitter electrode 11 can be increased from about 0.1 Pa to about 1 Pa. An upper limit of the pressure depends on a discharge phenomenon, and gas pressure at which a gas can be introduced differs depending on a potential difference between the emitter electrode 11 and a component having a ground potential or between the emitter electrode 11 and the extraction electrode 13, a gas mixing ratio, and the like. The inner wall may be cooled by the refrigerator 4. Since the inner wall surrounds the emitter electrode 11, an influence of thermal radiation from the vacuum chamber 17 can be reduced when the inner wall is cooled to the same degree as the emitter electrode 11. As long as the inside of the inner wall is maintained in an ultra-high vacuum state, the entire vacuum chamber 17 does not necessarily need to be maintained in an ultra-high vacuum state.

The vacuum partition wall 118 and the extraction electrode 13 are electrically insulated from the emitter electrode 11 by an insulator 117. When such a vacuum partition wall 118 is used to surround the emitter electrode 11, in relation to the introduction of a nitrogen gas used in FCE processing, a method in which a tip end of the gas nozzle 391 is disposed outside the vacuum partition wall 118 and the nitrogen gas is indirectly introduced into a periphery of the emitter electrode 11 through an extraction electrode hole 131 is suitable for precisely controlling pressure of the nitrogen gas related to a processing speed of a tip end of the emitter electrode 11. This is because, when a nozzle the same as that of hydrogen is disposed inside, it is difficult to measure introduction pressure of inside nitrogen, and a fluctuation of pressure of the inside nitrogen caused by an operation amount of the gas flow rate adjusting valve 394 becomes large. Further, from the viewpoint of controlling pressure of the nitrogen gas, it is preferable that the tip end of the gas nozzle 391 be close to a vacuum exhaust port of the vacuum evacuation device 16. This makes it easier to reflect a pressure change around the emitter electrode 11 due to an operation of the flow rate adjusting valve 394.

Since the ion beam 15 emitted from the emitter electrode 11 has fairly high directivity, a position and an angle of the emitter electrode 11 may be adjusted by an emitter electrode drive mechanism 18, which is an advantageous condition for focusing a probe current 151. The emitter electrode drive mechanism 18 can be manually adjusted by a user or can be automatically adjusted by an emitter electrode drive mechanism controller 181.

The ion beam device 1000 includes the gas field ionization source 1, a beam irradiation column 7, and a sample chamber 3. The ion beam 15 emitted from the gas field ionization source 1 passes through the beam irradiation column 7 and is radiated onto a sample 31 placed on a sample stage 32 inside the sample chamber 3. Secondary particles emitted from the sample 31 are detected by a secondary particle detector 33.

The beam irradiation column 7 includes a focusing lens 71, an aperture 72, a deflector 731, and an objective lens 76. The focusing lens 71, the deflector 731, and the objective lens 76 are supplied with voltages respectively from a focusing lens power supply 711, a deflector power supply 736, and an objective lens power supply 761. Electrodes of a deflector can be configured with a plurality of electrodes for generating an electric field having 4 poles, 8 poles, 16 poles, and the like as needed. It is necessary to increase the number of poles of a power supply of each deflector according to the number of electrodes. The number of deflectors in the beam irradiation column 7 may be increased as needed. It is needless to say that a power supply for supplying a voltage may be increased by a corresponding amount.

The ion beam 15 is focused by the focusing lens 71, a beam diameter thereof is limited by the aperture 72 similar to the probe current 151, and the ion beam 15 is further focused by the objective lens 76 to have a fine shape on a sample surface. The deflector 731 is used during an axis adjustment to reduce an aberration at the time of focusing a beam by a lens, during ion beam scanning on a sample, and during supplying a beam to a Faraday cup 19. An ion beam current supplied to the Faraday cup 19 is measured by an ammeter 191 and is digitized. Such a current measurement can also be performed by providing a Faraday cup 35 in the sample chamber 3. In this case, a beam can be supplied to the Faraday cup 35 by moving the Faraday cup 35 to an irradiation position of the ion beam 15 by a drive mechanism of the sample stage 32. An ion beam current supplied to the Faraday cup 35 is measured by an ammeter 351 and is digitized.

The beam irradiation column 7 is evacuated using a vacuum pump 77. The sample chamber 3 is evacuated using a vacuum pump 34. A differential exhaust structure may be provided between the gas field ionization source 1 and the beam irradiation column 7 and between the beam irradiation column 7 and the sample chamber 3 as needed. That is, a space between the gas field ion source 1 and the beam irradiation column 7 and a space between the beam irradiation column 7 and the sample chamber 3 other than opening portions through which the ion beam 15 passes may be kept airtight. With such a configuration, when a sample is introduced into the sample chamber 3, an amount of a generated residual gas flowing into the gas field ionization source 1 is reduced, and an influence of the gas is reduced. Conversely, an amount of a gas introduced into the gas field ionization source 1 flowing into the sample chamber 3 is reduced, and an influence of the gas is reduced.

For example, a turbo-molecular pump, an ion sputtering pump, a non-evaporable getter pump, a sublimation pump, or a cryopump is used as the vacuum pump 34. The vacuum pump 34 is not necessarily a single pump, and a plurality of the above described pumps may be combined as the vacuum pump 34. In conjunction with the gas introduction mechanism 38 to be described later, the device may operate the vacuum pump 34 only when a gas is introduced from the gas nozzle 381, or a valve may be provided between the vacuum pump 34 and the sample chamber 3 to adjust an exhaust amount.

The ion beam device 1000 may be installed on, for example, a device stand 60 including a vibration prevention mechanism 61 and a base plate 62 to prevent vibrations of the emitter electrode 11 of the gas field ionization source 1, the sample 31 placed inside the sample chamber 3, and the like, and prevent deterioration of sample observation and processing performance. The vibration prevention mechanism 61 may be made of, for example, an air spring, a metal material, a gel material, and rubber. Although not shown, a device cover may be provided to cover the entire or a part of the ion beam device 1000. It is preferable that the device cover be made of a material that can block or attenuate an external air vibration.

A sample exchange chamber (not shown) may be provided in the sample chamber 3. When the sample exchange chamber can perform preliminary evacuation for exchanging the sample 31, it is possible to reduce a deterioration degree of vacuum of the sample chamber 3 at the time of sample exchange.

The high-voltage power supply 111, the high-voltage power supply 112, the focusing lens power supply 711, the objective lens power supply 762, and the deflector power supply 736 can adjust a scanning range, a scanning speed, a scanning position, and the like of the ion beam 15 by automatically changing an output voltage, a cycle of the output voltage, and the like using a calculation device. The emitter electrode drive mechanism controller 181 can be automatically changed by the calculation device. A control condition value may be stored in the calculation device in advance, and may be immediately called and set to be the condition value when necessary.

### Embodiment 1: Method for Sharpening Emitter

In the case of using a GFIS, there are the above-described problems when sharpening the emitter electrode 11. A method is also conceivable in which an FIM device is prepared separately from a GFIS-SIM main body, and an atomic sharpness structure of the emitter electrode 11 is prepared in the FIM device, and then the atomic sharpness structure is transferred to the GFIS-SIM device. In this method, it is required to transfer the emitter electrode 11 having an atomic sharpness structure created in a vacuum environment of the FIM device to the GFIS-SIM after the emitter electrode 11 is exposed to the atmosphere once. The atomic sharpness structure is not always retained during the exposure to the atmosphere. Further, even when the atomic sharpness structure is transferred successfully and reaches the GFIS-SIM, reproduce processing is required when the structure is damaged, and replacement of the emitter electrode 11 is unavoidable. In terms of an improvement in the degree of vacuum in the device by using baking or time for cooling the emitter electrode 11 again by the refrigerator body 41, this method is not practical.

The invention is made in view of such a situation, and the inventors of the present application found that the atomic sharpness structure of the emitter electrode 11 can be stably and repeatedly formed without impairing resolution of an observation ion beam by performing FCE processing under the following conditions.

Helium from the gas cylinder 386 is introduced to a periphery of the emitter electrode 11 through the gas nozzle 381 after a flow rate of the helium is adjusted by the flow rate adjusting valve 384. Although not shown, pressure inside the gas field ionization source 1 may be measured by a gas pressure measuring machine, and the flow rate adjusting valve 384 may be automatically adjusted using a measured value. Before processing the emitter electrode 11, the high-voltage power supply 111 and the high-voltage power supply 112 are used to apply high voltages (extraction voltages) to respective electrodes between the emitter electrode 11 and the extraction electrode 13, and a positive strong electric field is generated at the tip end of the emitter electrode 11, so that processing of adjusting an initial shape of atoms at the tip end of the emitter electrode 11 by a phenomenon called field evaporation may be performed at an initial stage. The tip end of the emitter electrode 11 can be adjusted, by field evaporation processing, to a shape determined to a certain extent according to a magnitude of the electric field. This processing can increase uniformity of the FCE processing to a certain extent.

After the field evaporation processing, a current amount of helium ions is measured via the Faraday cup 19 or the Faraday cup 35. When the current amount of helium ions is measured, dependence of the current amount is grasped by changing an extraction voltage. A value of the electric field of the emitter electrode 11 can be indirectly grasped based on the dependence of the extraction voltage of the helium ion current.

Thereafter, a nitrogen gas serving as an FCE processing gas from the gas cylinder 396 is introduced to a periphery of the emitter electrode 11 through the gas nozzle 391 after a flow rate of the nitrogen gas is adjusted by the flow rate adjusting valve 394. Pressure inside the gas field ionization source 1 may be measured by a gas pressure measuring machine 377, and the flow rate adjusting valve 394 may be automatically adjusted using a measured value. At this time, the helium gas may be continuously supplied to the periphery of the emitter electrode 11 without stopping the supply of the helium gas. The electric field at the tip end of the emitter electrode 11 may be determined based on dependence of an extraction voltage of a helium current. Specifically, the electric field is strengthened to such an extent that the nitrogen gas cannot reach a tip end 120 of the emitter electrode 11 and helium ions are generated at the tip end 120. Further, the high-voltage power supply 111 and the high-voltage power supply 112 are adjusted to generate an electric field to such an extent that the nitrogen gas can reach an emitter shank 121 and react with metal atoms constituting the emitter electrode 11.

In the related art, it is required to control the FCE processing by monitoring the tip end of the emitter electrode 11 using a position-sensitive detector such as an MCP, but it is difficult to perform the FCE processing in a main body of a GFIS-SIM. Here, the present inventors found that the FCE processing can be controlled by monitoring, using the Faraday cup 19 or the Faraday cup 35, a current amount of a helium ion beam of which a radiation angle is appropriately limited. That is, the present inventors found for the first time that there is a close relationship between a current amount of a helium ion beam and tip end sharpness of the emitter electrode 11 as described below.

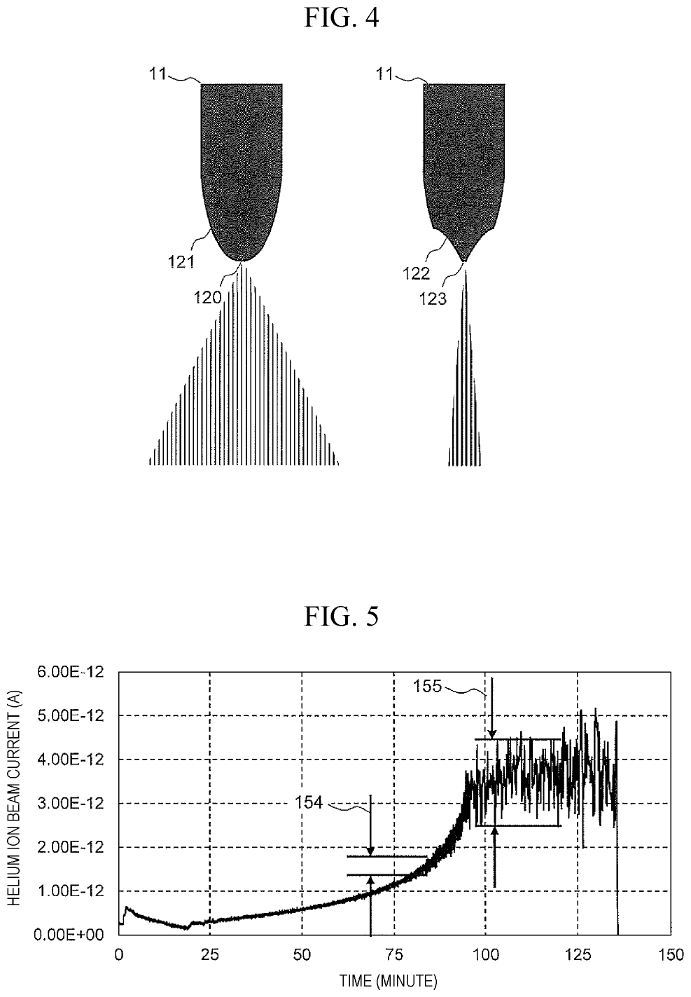

FIG. 4 is a schematic view showing a state in which the tip end of the emitter electrode 11 is sharpened by the FCE processing. Immediately after the start of the FCE processing, that is, immediately after the field evaporation processing, the tip end of the emitter electrode 11 is formed into a hemispherical shape corresponding to an intensity of an electric field at the time of the field evaporation processing, and thus the intensity of the electric field is uniform (a left view in FIG. 4). Accordingly, helium ions are uniformly emitted onto a surface of the emitter tip end. Therefore, a current amount in an introduction angle is relatively small. In other words, when the supply of an ionized helium gas is constant, a total amount of a current ionized at the tip end 120 of the emitter electrode 11 is roughly rate-determined by gas pressure, and thus how an intensity of an ionized electric field is distributed at the emitter tip end affects a density of an ion current.

As the FCE processing progresses, the emitter shank 121 is deformed as shown in a right view in FIG. 4. Even when an extraction voltage is applied to an FCE processed portion 122, an electric field is weak, and ionization of the helium ion beam does not occur. Therefore, consumption of the helium gas whose supply is limited, that is, generation of helium ions is concentrated in the vicinity of a tip end sharp portion 123. Accordingly, an introduction angle is limited, and a current amount of the helium ion beam that passed through increases as the FCE processing progresses.

The inventors further found that a relationship between the current amount of the helium ion beam and a shape of the tip end of the emitter electrode 11 is also related to an evaporation phenomenon of tip end atoms. When the extraction voltage is maintained during the FCE processing, sharpening of the emitter electrode 11 progresses as shown in the right view in FIG. 4. Accordingly, an electric field of the tip end sharp portion 123 becomes strong. When the electric field is larger than a field evaporation intensity specific to metal atoms constituting the emitter electrode 11, field evaporation of metal atoms of the tip end sharp portion 123 starts. The field evaporation of the metal atoms at the tip end causes a change in unevenness of a tip end structure, that is, a change in an electric field distribution of the electric field at the tip end.

When the distribution of the electric field at the tip end changes, a current of the helium ion beam may change. The inventors of the present application found that the emitter shank 121 is reduced by the FCE processing, the tip end sharp portion 123 is formed accompanying with the sharpening of the tip end 120, and further the sharpening of the tip end sharp portion 123 progresses, so that an influence of a change in unevenness of a structure of the tip end sharp portion 123 on a change in a current of the helium ion beam increases. For example, when sharpness of the tip end sharp portion 123 is formed by 1000 atoms in the tip end sharp portion 123, a structure change due to field evaporation of one atom has an influence of about 0.1%, when the sharpness is formed by 100 atoms, the structure change has an influence of 1%, and when the sharpness is formed by 10 atoms, the structure change has an influence of 10%. A change in the number of atoms is not only influenced by a change in a magnitude of an electric field due to a change in the structure, but also is greatly influenced by a change in a supply amount of an ionized helium gas.

From all of these results, as the tip end sharpness increases, an influence on a current amount of the helium ion beam becomes larger due to a change in an atomic structure caused by field evaporation and a change in the number of constituent atoms.

FIG. 5 shows data indicating transition of the current amount of the helium ion beam whose detection angle is appropriately limited, which is actually detected during the FCE processing. Immediately after the FCE processing is started, a current of the helium ion beam is relatively small as described above. As the FCE processing progresses, the current of the helium ion beam increases as a whole, and a current fluctuation range also increases.

In the transition of the current amount of the helium ion beam shown in FIG. 5, a current fluctuation range 154 evaluated at a time point of 74 minutes is 1 pA or less, which is fairly small, whereas a current fluctuation range 155 at a time point of 100 minutes and subsequent time points after the FCE processing progresses is 1 pA or more.

A current increase rate per unit time also changes for the same reason as the current fluctuation. That is, when an FCE processing gas such as a nitrogen gas is kept constant, an increase rate is high in a situation where sharpening progresses. For example, a current increase amount from 50 minutes to 75 minutes in FIG. 5 is about 0.5 pA, and a current increase amount from 75 minutes to 100 minutes is about 2 pA.

The reason why a current value increases with the progress of sharpening is considered to be that a current density on a detection surface increases due to sharpening of a shape of an ion beam. In other words, it is desirable in the invention that an introduction angle of the detection surface be limited to such an extent that the current density increases. A specific example for limiting the introduction angle will be described later.

It is considered that the reason why a current fluctuation range increases as the sharpening progresses is that the sharpening progresses while a time point when an atomic configuration suitable for strongly emitting an ion beam appears on a surface of the emitter electrode 11 and a time point when an atomic configuration for weakly emitting an ion beam appears are repeated with the field evaporation of the emitter electrode 11. In other words, when the current fluctuation range is large, it is estimated that the field evaporation of the emitter electrode 11 also progresses. That is, it can be estimated that sharpening progresses.

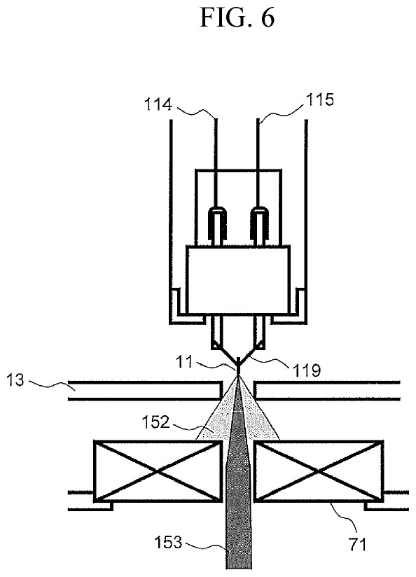

FIG. 6 is an enlarged view showing a periphery of the emitter electrode 11 and showing a state in which an introduction angle of a helium ion beam is limited. A relationship between a current of the helium ion beam and the sharpness of the emitter electrode 11 as shown in FIG. 5 becomes noticeable when the introduction angle of the helium ion beam is limited. FIG. 6 shows a configuration example for this purpose. A voltage lead wire 114, a voltage lead wire 115, and a filament 119 will be described in a second embodiment.

It is necessary to appropriately narrow a beam at a position from the extraction electrode 13 to the focusing lens 71 or the aperture 72. Further, it is necessary to appropriately set an opening diameter of the extraction electrode 13 and an opening diameter of the focusing lens 71 or the aperture 72 based on a positional relationship of elements. It is necessary that an introduction angle on a detection surface of an ion beam detector is limited to 100 mrad or less when the introduction angle is converted into an emission angle at a position of the emitter electrode 11. For example, an opening for limiting a beam may be separately provided in the focusing lens 71. In this manner, it is not necessary to directly radiate the ion beam to the focusing lens, and an influence of performance deterioration due to contamination can be reduced. It is assumed that the contamination in this case is caused by the beam hitting the focusing lens, and thus an unintended substance is deposited on an irradiated portion. When the temporarily deposited substance is an insulator, it is assumed that performance is lowered, for example, a focusing diameter of the beam is large due to an electrification phenomenon and the beam vibrates.

When the introduction angle is limited by a lower portion of the focusing lens 71, for example, by the aperture 72, the introduction angle can be adjusted by a value of a voltage applied to the focusing lens 71. Specifically, in a case where a beam focusing position of the focusing lens 71 is below the aperture 72, when a focusing action of the focusing lens 71 is weakened and the focusing position is lowered, the introduction angle tends to be narrow and the focusing action tends to be strengthened, and when the focusing position is raised, the introduction angle tends to be wide. With such an adjustment, it is possible to adjust a correlation between a fluctuation of a detected current amount of the helium ion beam and a structure change of a tip end of an emitter tip. That is, an ion beam current amount distributed at a position where a detection angle is wide mainly reflects an emission amount from an outer side of the tip end of the emitter tip, and conversely, the ion beam current amount distributed at a position where the detection angle is narrow reflects an emission amount from the vicinity of the tip end of the emitter tip. By changing the focusing action of the focusing lens 71, it is possible to change, based on a fluctuation of an ion beam, whether a change in the vicinity of the tip end can be grasped more quickly or a change in the entire emitter tip end can be grasped. Such an adjustment has an effect of improving accuracy of checking progress of the FCE processing.

An end determination of the FCE processing and an adjustment of a processing speed may be performed by using the correspondence relationship shown in FIG. 5. Specifically, a current absolute value, a current increase rate, a current amplitude, and a current period are measured and detected by the ammeter 191 or the ammeter 351 connected to the Faraday cup 19 or the Faraday cup 35. These results are transmitted to an FCE control device 113. The FCE control device 113 can stop, slow, or end the FCE processing by controlling the high-voltage power supply 111, the high-voltage power supply 112, and a valve adjusting mechanism 393. More specifically, when an opening degree of the flow rate adjusting valve 394 is adjusted in an opening direction and pressure of a nitrogen gas around the emitter electrode 11 is increased, a speed of the FCE processing is increased. Conversely, when an opening degree of the flow rate adjusting valve 394 is adjusted in a closing direction and pressure of the nitrogen gas around the emitter electrode 11 is reduced, the speed of the FCE processing is reduced. The FCE processing can be ended by adjusting a power supply in a direction of reducing a potential difference between the emitter electrode 11 and the extraction electrode 13 or adjusting the power supply to zero. For example, the pressure of the nitrogen gas is reduced at around an elapsed time of 95 minutes in the example shown in FIG. 5. It is understood that a current fluctuation period is delayed from around this time point. This is because a speed of the FCE processing is reduced due to reduction in the pressure of the nitrogen gas, and a frequency of electrolytic evaporation of tip end atoms is reduced.

A current absolute value of a helium ion beam is substantially proportional to pressure of a helium gas introduced to a periphery of the emitter electrode 11 using the gas introduction mechanism 38. That is, for example, a numerical value such as a current absolute value in FIG. 5 have no essential meaning, and it should be noted that the numerical value differs depending on conditions such as introduction pressure of helium and an extraction voltage, and a design value of a device such as an introduction angle of a helium ion beam.

### Embodiment 1: Summary

The ion beam device 1000 according to Embodiment 1 monitors the sharpness of the emitter electrode 11 based on a current value of a helium ion beam when the emitter electrode 11 is sharpened using a nitrogen gas or an oxygen gas. Accordingly, a gas supply amount, an extraction voltage, and the like can be adjusted according to a monitoring result. Therefore, it is not necessary to provide, in advance, a detector such as an MCP in the ion beam device 1000 in order to monitor the sharpness. Further, since a process of inserting a detector into and removing the detector from the ion beam device 1000 for monitoring is not necessary, there is no device downtime associated with monitoring.

In the ion beam device 1000 according to Embodiment 1, the relationship shown in FIG. 6 is established between a current of the helium ion beam and the sharpness of the emitter electrode 11 by limiting an introduction angle of the helium ion beam. Accordingly, the relationship between the current of the helium ion beam and the sharpness of the emitter electrode 11 can be accurately specified, and thus monitoring accuracy of the sharpness is improved.

### Embodiment 2

In Embodiment 2 according to the invention, a hydrogen gas is used as a gas used by the ion beam device 1000 for sharpening the emitter electrode 11 in addition to the gas in Embodiment 1. Other configurations are the same as those in Embodiment 1.

A nitrogen gas or an oxygen gas used in FCE has a large chemical action on a metal such as tungsten and iridium and is excellent in processing speed, but has a disadvantage in that an aggregation temperature is considerably higher than that of a helium gas or a hydrogen gas used in a GFIS-SIM. Although brightness of an ion beam emitted from the GFIS depends on a cooling temperature of an emitter, a vicinity of an aggregation temperature of a used gas is often optimum for increasing the brightness of the ion beam. That is, it means that an optimum operation temperature of the GFIS that emits helium or hydrogen is lower than an aggregation temperature of a nitrogen gas or an oxygen gas. For example, a failure occurs in an atomic structure of an emitter tip end in the GFIS that operates at a temperature in the vicinity of an optimum temperature of a hydrogen ion beam. In order to use a nitrogen gas to readjust the atomic structure in the FCE, an operation temperature is to be increased once to be higher than an aggregation temperature of the nitrogen gas. Temperature increasing processing of the GFIS and cooling processing after the FCE require approximately half a day at most. This causes a problem that a device downtime increases. When the temperature increasing processing and the cooling processing are omitted and the nitrogen gas is introduced at a brightness optimized temperature, the nitrogen gas is aggregated, and there is a problem that it is fairly difficult to perform a precise adjustment of gas pressure required in the FCE.

The inventors of the present application found that an FCE processing speed contributing to tip end processing of the emitter electrode 11 can be obtained by using a hydrogen gas which is considered to have no or small FCE effects in combination with heat processing.

At an optimum operation temperature (specifically, about 50 K or lower) of the hydrogen gas, an effect of processing the emitter shank 121 for a metal (specifically, a metal such as tungsten, iridium, platinum, or gold) used for an emitter tip is small. Therefore, a hydrogen ion beam can be stably generated from the GFIS.

In order to perform the FCE processing in the hydrogen gas, the hydrogen gas is introduced to a periphery of the emitter electrode 11 using the gas introduction mechanism 37, and an extraction voltage is applied using the high-voltage power supply 111 and the high-voltage power supply 112. An electric field at the tip end is maintained at about an electric field of a threshold at which a metal constituting the emitter electrode 11 is field evaporated. This electric field is typically larger than an electric field for ionizing the hydrogen gas, and not much ionization of the hydrogen gas occurs at the tip end. Further, a current is supplied to the filament 119 through the voltage lead wire 114 and the voltage lead wire 115. As a current source, a floating DC power supply (not shown) may be incorporated in the high-voltage power supply 111. The filament 119 is heated by Joule heat, thereby heating the emitter electrode 11. Accordingly, a temperature of the emitter electrode 11 cooled to 50 K or lower is increased to, for example, a room temperature or higher. As the temperature rises, the FCE processing using the hydrogen gas progresses in a similar manner to the FCE processing using a nitrogen gas.

Since the emitter electrode 11 is heated by heating during the FCE processing using hydrogen, monitoring using a current of a helium ion beam is difficult. This is because a current amount is reduced by heating, which makes detection difficult. By intermittently stopping the current introduced into the filament 119, the heating of the emitter electrode 11 is stopped, and a state of the tip end of the emitter electrode 11 can be monitored using a current amount of a helium ion beam. During a period in which the current is intermittently stopped, the emitter electrode 11 is cooled again by the refrigerator 4 via an emitter base 116 to a temperature of 50 K or lower. When the emitter electrode 11 is cooled, the current amount of the helium ion beam recovers and can be reused for monitoring the tip end of the emitter electrode 11.

Instead of structure monitoring using a helium ion beam, it is also possible to monitor sharpness using a current amount of a hydrogen ion beam. In this method, a type of gas to be introduced is one type of the hydrogen gas, and the method is fairly simple. When monitoring is performed using a hydrogen ion beam, it is required to return the temperature of the emitter electrode 11 to a temperature lower than that in the FCE processing using a hydrogen ion beam. This cooling can be achieved by the refrigerator 4 as described above.

The device may be implemented such that setting values such as a voltage of a required power supply, for example, an FCE processing mode using a hydrogen ion beam, a structure monitoring mode using a current of a hydrogen ion beam, and a surface observation mode of the sample 31 using a hydrogen ion beam, are stored in the FCE control device 113 or the like, and setting of the high-voltage power supply 111, the high-voltage power supply 112, and a DC power supply for heating a filament incorporated in the high-voltage power supply 111 is instantaneously switched.

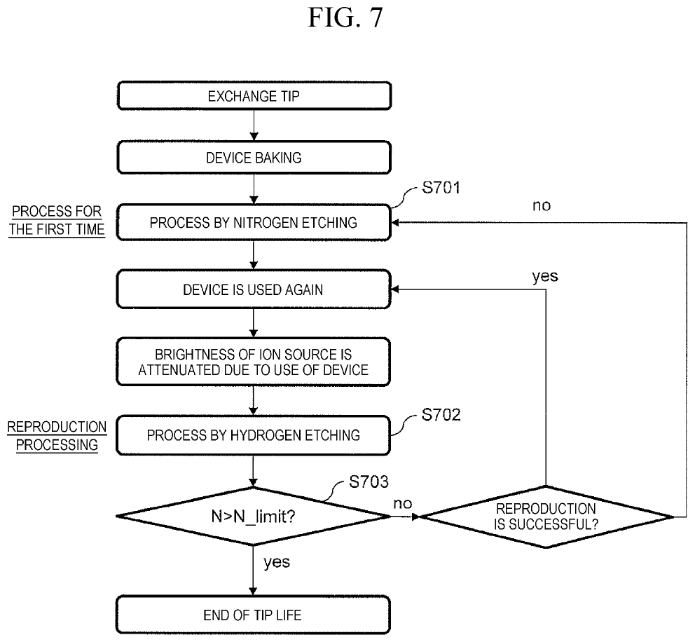

FIG. 7 is a flowchart showing a procedure for performing the FCE processing using a hydrogen gas. Even when the FCE processing using a hydrogen gas can be performed by heating the emitter electrode 11, a processing speed at a temperature (specifically, 400° C. or lower) equal to or lower than a temperature at which the filament is red-heated does not reach a processing speed in the FCE processing using a nitrogen gas or an oxygen gas. Therefore, as shown in the flowchart in FIG. 7, the FCE processing using a nitrogen gas or an oxygen gas is performed when sharpness of a structure of the emitter electrode 11 is to be changed greatly, for example, immediately after a replacement of the emitter electrode 11 or when a shape of the tip end is damaged greatly and cannot be reproduced by hydrogen gas etching processing (S701), and the FCE processing using a hydrogen gas is performed when the sharpness of the emitter electrode 11 is intended to be changed slightly, for example, when a structure of the tip end is broken slightly (S702). Accordingly, a device downtime is greatly reduced. When the number of times of hydrogen etching processing exceeds an upper limit value N_limit (S703: yes), it is considered that the emitter electrode 11 reaches the end of its life, and replacement or the like is appropriately performed. It is desirable to use a nitrogen gas or an oxygen gas when the emitter electrode 11 is processed for the first time (when S701 is performed for the first time).

When only the FCE processing using a hydrogen gas is used without using the FCE processing using a nitrogen gas, in order to bring a processing speed close to a processing speed in the FCE processing using a nitrogen gas, a temperature needs to be increased to at least about the vicinity of 600° C. at which the filament is red-heated. In this case, since fairly precise temperature control of the filament is required, a DC power supply incorporated in the high-voltage power supply 111 may control the temperature using a resistance value of the filament 119.

When the FCE processing using a nitrogen gas is performed, it is preferable to increase the temperature of the emitter electrode 11 as compared with a case where a hydrogen ion beam is extracted for observation. This is because an aggregation temperature of the nitrogen gas is higher than that of the hydrogen gas, and the nitrogen gas is easily adsorbed to a surface at an optimum operation temperature of the GFIS and is easily left in the device as compared with the hydrogen gas.

After the emitter is processed by the FCE processing using nitrogen, the nitrogen gas is preferably removed from an ion source in order to stabilize a current value of a hydrogen ion beam for observation. In the case of using, as the vacuum evacuation device 16, an evacuation unit of a type requiring re-activation in an accumulating manner, such as an evacuation unit based on a physical adsorption or a chemical adsorption action using a non-evaporable getter agent or an evacuation unit of a titanium sublimation type, it is preferable to perform the re-activation immediately after the FCE processing using the nitrogen gas. One reason is that the nitrogen gas is accumulated in the vacuum evacuation units by introducing the nitrogen gas by the FCE processing. Another reason is that since the temperature of the emitter electrode 11 is increased by the FCE processing, a probability that a residual gas emitted at the time of the re-activation is adsorbed on a surface of a component disposed inside a vacuum chamber is reduced. Therefore, it is desirable to perform the re-activation after sharpening the emitter electrode 11 with the nitrogen gas (or the oxygen gas) and before a step of cooling the ion beam device 1000 (or the gas field ionization source 1).

### Embodiment 2: Summary

The ion beam device 1000 according to Embodiment 2 uses the FCE processing using a hydrogen gas in combination with the FCE processing using a nitrogen gas or an oxygen gas. As a result, the FCE processing can be performed by heating the filament only, and processing of adjusting a temperature of the entire GFIS required before and after the FCE processing using the nitrogen gas can be omitted. Accordingly, a device downtime can be reduced.

The ion beam device 1000 according to Embodiment 2 may periodically perform emitter sharpening by the FCE processing using the nitrogen gas or the oxygen gas, for example, at an appropriate cycle. Accordingly, sharpening using a hydrogen ion beam can be performed in a normal time, and the sharpness can be maintained at a level equal to or higher than a reference value at an appropriate timing such as a time of regular maintenance.

### Modifications of the Invention

The invention is not limited to the embodiments described above, and includes various modifications. For example, the above-described embodiments are described in detail for easy understanding of the invention, and the invention is not necessarily limited to those including all the configurations described above. A part of a configuration of one embodiment can be replaced with a configuration of another embodiment, and a configuration of another embodiment can be added to the configuration of the one embodiment. In addition, it is possible to add, delete, or replace a part of a configuration of each embodiment with another configuration.

In the above embodiments, the FCE control device 113 may control the entire operation of the ion beam device 1000 without being limited to the FCE processing. The FCE control device 113 may be configured with hardware such as a circuit device in which such a function is implemented, or may be configured with a calculation device such as a central processing unit (CPU) executing software in which such a function is implemented.

In the above embodiments, adjusting processing of aligning an orientation direction of atoms constituting the emitter electrode 11 and an emission direction of an ion beam may be performed before irradiation of each ion beam. This adjustment can be performed by adjusting a position or an inclination of the emitter electrode 11 by the emitter electrode drive mechanism 18 or the emitter electrode drive mechanism controller 181.

### REFERENCE SIGNS LIST

1: gas field ionization source
11: emitter electrode (emitter tip)
111: high-voltage power supply
112: high-voltage power supply
113: FCE control device
13: extraction electrode
16: vacuum evacuation device
17: vacuum chamber
37: gas introduction mechanism
38: gas introduction mechanism
4: refrigerator
1000: ion beam device

1. An ion beam device that observes or processes a sample by irradiating the sample with an ion beam, the ion beam device comprising:
an emitter tip having a needle-shaped tip end;
an extraction electrode facing the emitter tip and having an opening at a position away from the emitter tip;
a gas supply source configured to supply a helium gas to a vicinity of the emitter tip and supply at least one of a nitrogen gas and an oxygen gas;
a voltage applying unit configured to apply a voltage to between the emitter tip and the extraction electrode to cause the emitter tip to radiate the ion beam;
a current measuring unit configured to measure a current amount of the ion beam; and
a gas flow rate adjusting mechanism configured to adjust a flow rate of a gas supplied from the gas supply source, wherein
the current measuring unit measures at least one of a current amount of a helium ion beam, a time increase rate of the current amount of the helium ion beam, and a fluctuation range of the current amount of the helium ion beam, and
the ion beam device sharpens the emitter tip by performing, according to a measurement result of the helium ion beam performed by the current measuring unit, at least one of a first operation of adjusting a flow rate of the nitrogen gas or the oxygen gas supplied by the gas flow rate adjusting mechanism and a second operation of adjusting the voltage applied by the voltage applying unit.

2. The ion beam device according to claim 1, further comprising:
a focusing lens configured to focus the ion beam; and
an aperture configured to narrow a diameter of the ion beam, wherein
when the current measuring unit measures the helium ion beam, an introduction angle of the helium ion beam is limited by at least one of introduction angle conditions including
an opening diameter of the extraction electrode, a position of the focusing lens, a position of the aperture, or an opening diameter of the aperture.

3. The ion beam device according to claim 2, wherein
the introduction angle is adjustable by changing strength of a focusing action of the focusing lens.

4. The ion beam device according to claim 1, further comprising:
a partition wall surrounding the emitter tip, a part of the partition wall being configured with the extraction electrode;
a helium gas flow path protruding into a space surrounded by the partition wall to directly supply a helium gas into the space; and
a nitrogen gas flow path configured to supply a nitrogen gas to outside of the space surrounded by the partition wall, wherein
the nitrogen gas flow path indirectly supplies the nitrogen gas into the space through an opening of the extraction electrode.

5. The ion beam device according to claim 4, further comprising:
a vacuum evacuation pump configured to evacuate a periphery of the emitter tip, wherein
a front end of the nitrogen gas flow path is disposed closer to an intake port of the vacuum evacuation pump than to the opening of the extraction electrode.

6. The ion beam device according to claim 1, further comprising:
a control unit configured to detect the current amount of the helium ion beam and control an operation of processing the emitter tip, wherein
the control unit controls the gas flow rate adjusting mechanism to supply a helium gas to the vicinity of the emitter tip and supplies a nitrogen gas or an oxygen gas at the same time, thereby sharpening the emitter tip using the nitrogen gas or the oxygen gas and at the same time, monitoring sharpness of the emitter tip using the helium gas.

7. The ion beam device according to claim 1, further comprising:
a control unit configured to control an operation of processing the emitter tip using information of the ion beam; and
a heating unit configured to heat the emitter tip, wherein
the control unit is switchable between
a first processing mode for sharpening the emitter tip by supplying a nitrogen gas or an oxygen gas from the gas supply source, and
a second processing mode for sharpening the emitter tip by supplying a hydrogen gas from the gas supply source and heating the emitter tip, and
the control unit executes the first processing mode at least once before executing the second processing mode.

8. The ion beam device according to claim 1, further comprising:
a control unit configured to control an operation of processing the emitter tip using information of the ion beam, wherein
the control unit controls the gas supply source, the voltage applying unit, and the gas flow rate adjusting mechanism to switch between the first operation and the second operation.

9. A method for processing an emitter tip of a gas field ionization source, the method comprising:
a step of sharpening the emitter tip by supplying a nitrogen gas or an oxygen gas to a vicinity of the emitter tip and applying a voltage to the emitter tip; and
a step of sharpening the emitter tip by supplying a hydrogen gas to the vicinity of the emitter tip and heating the emitter tip, wherein
the step of sharpening the emitter tip using the nitrogen gas or the oxygen gas is performed at least once before the step of sharpening the emitter tip using the hydrogen gas.

10. The method according to claim 9, further comprising:
a step of obtaining an observation image of a sample by irradiating the sample with a hydrogen ion beam generated from the emitter tip, wherein
in the step of sharpening the emitter tip using the hydrogen gas, the emitter tip is heated to a temperature higher than a temperature in the step of obtaining the observation image of the sample.

11. The method according to claim 9, wherein
the gas field ionization source further includes a vacuum evacuation pump configured to evacuate the vicinity of the emitter tip by accumulating a gas in the vicinity of the emitter tip, and
the method further comprises a step of reactivating the vacuum evacuation pump after the step of sharpening the emitter tip using the nitrogen gas or the oxygen gas and before performing a step of cooling the gas field ionization source.

12. The method according to claim 9, wherein
the step of sharpening the emitter tip using the nitrogen gas or the oxygen gas is periodically repeated to maintain sharpness of the emitter tip at or above a reference level.
